(19) United States
(12) Patent Application Publication
(10) Pub. No.: US 2013/0217199 A1
(43) Pub. Date: Aug. 22, 2013

(54) METHOD FOR FABRICATING RESISTIVE MEMORY DEVICE

(71) Applicants: Ru Huang, Beijing (CN); Shenghu Tan, Beijing (CN); Lijie Zhang, Beijing (CN); Yue Pan, Beijing (CN); Yinglong Huang, Beijing (CN); Gengyu Yang, Beijing (CN); Yu Tang, Beijing (CN); Jun Mao, Beijing (CN); Yimao Cai, Beijing (CN)

(72) Inventors: Ru Huang, Beijing (CN); Shenghu Tan, Beijing (CN); Lijie Zhang, Beijing (CN); Yue Pan, Beijing (CN); Yinglong Huang, Beijing (CN); Gengyu Yang, Beijing (CN); Yu Tang, Beijing (CN); Jun Mao, Beijing (CN); Yimao Cai, Beijing (CN)

(73) Assignee: PEKING UNIVERSITY, Beijing (CN)

(21) Appl. No.: 13/580,952

(22) PCT Filed: Apr. 16, 2012
(86) PCT No.: PCT/CN12/74078

§ 371 Date: Aug. 23, 2012

(30) Foreign Application Priority Data
Feb. 21, 2012 (CN) 201210041447.4

(51) Int. Cl. H01L 21/02

(52) U.S. Cl. 438/382; 257/E21.004

(57) ABSTRACT

The present invention discloses a method for fabricating a resistive memory, including: fabricating a bottom electrode over a substrate; partially oxidizing a metal of the bottom electrode through dry-oxygen oxidation or wet-oxygen oxidation to form a metal oxide with a thickness of 3 nm to 50 nm as a resistive material layer; finally fabricating a top electrode over the resistive material layer. The present invention omits a step of depositing a resistive material layer in a conventional method, so as to greatly reduce the process complexity. Meanwhile, a self alignment between the resistive material layer and the bottom electrode can be realized. A full isolation between devices may be ensured so as to obviate the parasite effects occurred in the conventional process methods. Meanwhile, the actual area and designed area of the device are ensured to be consistent.

### CROSS-REFERENCE TO RELATED APPLICATION

The present application claims priority to Chinese application No. 201210041447.4, filed on Feb. 21, 2012, which is incorporated herein by reference.

### FIELD OF THE INVENTION

The present invention relates to the field of ultra-large scale integrated circuit technology, and particularly relates to a method for fabricating a nonvolatile resistive memory device.

### BACKGROUND OF THE INVENTION

As continuous development of integrated circuit technology, a flash technology based on a conventional floating gate structure is faced with a technology difficulty in scaling down. In recent years, a Resistance Random Access Memory (RRAM) based on Metal-Insulator-Metal (MIM) structure is widely concerned by academic community and industry community, due to the simple structure, easy fabrication, small size, high integrity , rapid erase and write speed, low power consumption and etc. As compared to a flash with a conventional floating gate structure that stores information 0 and 1 by means of charge, the resistive memory stores information 0 and 1 with a high resistance state and a low resistance state under different conditions respectively.

A memory cell of the resistive memory generally has three layer structure of metal/functional film layer/metal which may be fabricated by a typical film fabrication process such as sputtering, vapor deposition or the like. The resistive memory has a simple structure, and has a fabrication process compatible with a CMOS process. The erase and write speed of the resistive memory is decided by the width of a pulse which triggers a resistance transition, the width is generally less than 100 ns and far smaller than that of a flash memory. Moreover, a multi-level transition phenomenon is also existed in the RRAM, and more information may be stored by using the multiply resistance states. Thus, more information storage may be achieved without changing the volume of the memory cell. Therefore, the resistive memory has potential to substitute the flash memory in the future, and becomes a new generation of nonvolatile memory.

The resistive memory cell has a MIM capacitor structure in which an insulation layer or a semiconductor functional layer is interposed between a top electrode and a bottom electrode, which is also referred as a sandwich structure. A memory array may use a cross array structure which is also referred as crossbar. Such a crossbar structure has an easy process, a high density, and has a better scaling down ability. The fabrication process of a device with the MIM structure generally employs a three-layer process, including depositing a material of the bottom electrode (BE) and patterning by lift-off process, depositing a resistive material layer and etching the layer to form a connection hole, and depositing the top electrode (TE) and patterning by lift-off process. At present, the research of the resistive material of the RRAMare mainly focused on transition metal oxide such as NiO, TiO₂, Al₂O₃, Ta₂O₅. In general, these materials may be compatible with the CMOS process, and show better resistive characteristics. Meanwhile, these materials mostly may be obtained with high temperature oxidation.

However, base on the three-layer MIM process using sputtering and deposition, due to the full cover of a middle dielectric layer, dielectric layers between the BE (bottom electrode) and the TE (top electrode) are fully connected, the actual size of the device is far larger than a designed size. Hence, there are no complete isolations between devices, and the device parasitic effect is significant.

### SUMMARY OF THE INVENTION

In order to overcome shortages in the prior art, the present invention proposes a method for fabricating a resistive memory based on a bottom electrode oxidation method.

A technical solution of the present invention is as follow.

A method for fabricating a RRAM includes the following steps:

1) fabricating a bottom electrode over a substrate;

2) partially oxidizing the metal of the bottom electrode by a dry-oxygen oxidation or a wet-oxygen oxidation to form a metal oxide with a thickness of 3 nm to 50 nm as a resistive material layer;

3) fabricating a top electrode over the resistive material layer.

Wherein, in the step 1) or 3), the bottom electrode or the top electrode is fabricated by using a PVD method or other film formation method in IC process.

The bottom electrode may be formed of a metal which may form a corresponding metal oxide through high temperature oxidation, such as W electrode, Ta electrode, Ti electrode, Al electrode, Y electrode or Hf electrode.

The metal of the bottom electrode has a thickness in a range of 100 nm-300 nm.

The top electrode may be Pt electrode, TiN electrode, Cu electrode, Ag electrode or the like.

A protection electrode may be added onto the top electrode, and the protection electrode may be formed of platinum, titanium or gold.

As compared with the prior art, the present invention has the following advantageous technical effects.

In the present invention, a metal corresponding to a transition metal oxide with a RRAM characteristic is selected as a bottom electrode, the bottom electrode is oxidized directly after patterning the bottom electrode, and the metal of the bottom electrode is partially oxidized by controlling the oxidation condition to form a corresponding transition metal oxide as a resistive material layer. In the present invention, a step of depositing a resistive material layer in a conventional method is omitted, so that the process complexity is greatly reduced. Meanwhile, a self alignment between the resistive material layer and the bottom electrode is realized. A full isolation between devices may be ensured so as to obviate the numerous parasite effects occurred in the conventional process methods. And, the actual area and designed area of the device are ensured to be consistent. The present invention has a great application prospect in low voltage and low power consumption memory and embedded system in future.

### BRIEF DESCRIPTION OF THE DRAWINGS

FIG. 1 is a schematic diagram showing a cross sectional structure of a resistive memory of an embodiment of the present invention, in which,

1 denotes a silicon substrate, 2 denotes a bottom electrode, 3 denotes a resistive material layer, and 4 denotes a top electrode;

FIG. 2 is a graph showing a resistive characteristic of the resistive memory of an embodiment of the present invention, in which,

SET denotes a process of transiting from a high resistance state to a low resistance state; RESET denotes a process of transiting from a low resistance state to a high resistance state.

### DETAILED DESCRIPTION OF THE EMBODIMENTS

The present invention will be further described below in conjunction with the attached drawings.

### Embodiment 1

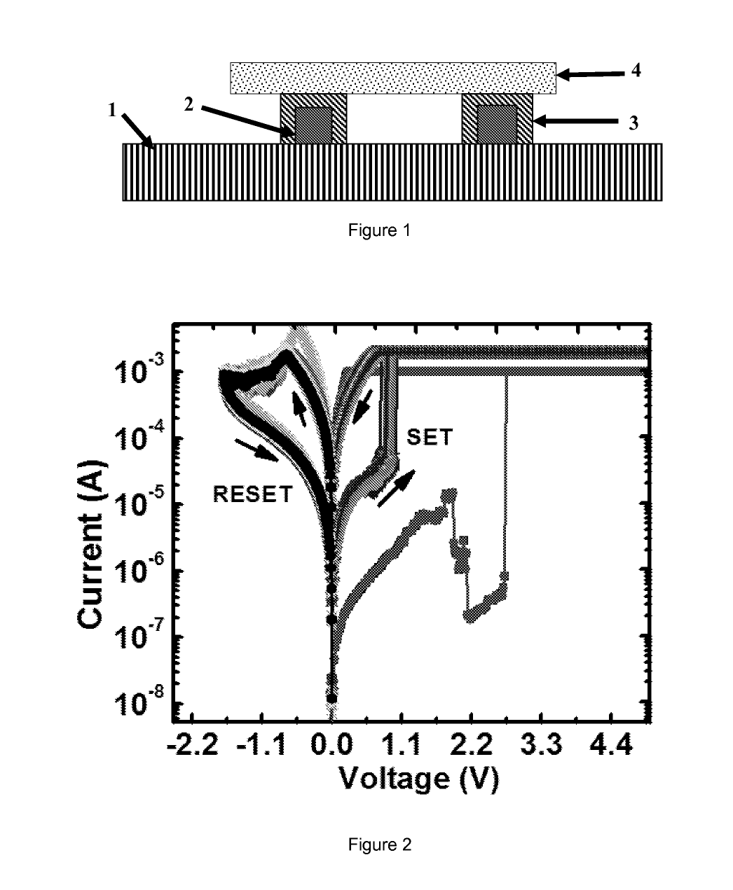

A resistive memory fabricated by the embodiment has a cross section structure as shown in FIG. 1. The fabrication process of the resistive memory of the embodiment will be described hereafter in conjunction with the schematic diagram of the cross section structure.

1) Firstly, a Ta metal layer of 200 nm is fabricated over a silicon substrate 1 by using physical vapor deposition (PVD) method or other film formation method in IC process.

2) A standard photolithography process and a lift-off process are performed. A bottom electrode is patterned to form the bottom electrode 2.

3) A TaOₓ (X=1-2.5) film of 10 nm covering the bottom electrode is formed by using dry-oxygen oxidation method in a high temperature oxidation furnace at temperature of 400° C. for 2 hours.

4) A via hole for the bottom electrode is formed by photolithography and etching process.

5) Like the fabrication of the bottom electrode, a top electrode TiN and a protection electrode Pt thereof are fabricated by using physical vapor deposition (PVD) method or other film formation method in IC process.

In the embodiment, a resistive memory device Ta/TaOₓ/TiN which is fully compatible with standard CMOS processes is fabricated by using a PECVD method. During the fabrication, there is no need to separately deposit an oxide film covering the whole wafer.

The resistive memory device Ta/TaOₓ/TiN fabricated by the embodiment has a resistive characteristic test result as shown in FIG. 2.

As seen from FIG. 2, as a voltage applied to the top electrode varies (the bottom electrode is grounded), the resistance of RRAM device according to the embodiment transits from high resistance state to low resistance state, and achieves the object of storing 0 and 1 in cases of a positive voltage turning-on or turning-off. It is also can be seen from FIG. 2, a forming voltage of the resistive memory of the embodiment is about 2.6V, thereafter, a turning-on voltage Von after normal operation is about 1.2V, a turning-off voltage Voff is about −1.8V.

A cycling test is performed for the embodiment for 50 times, the result of the test shows that the device has an excellent stability and repeatability.

### Embodiment 2

1) Firstly, a W layer of 200 nm is fabricated over a silicon substrate 1 by using physical vapor deposition (PVD) method or other film formation method in IC process.

2) A standard photolithography process and lift-off technology are performed. A bottom electrode is patterned to form the bottom electrode.

3) A WOₓ (X=1-3) film of 10 nm covering the bottom electrode is formed by using wet-oxidation method in a oxidation furnace at temperature of 400° C. for 3 hours.

4)A Via hole for bottom electrode is formed by lithography and etching process.

5) Like the fabrication of the bottom electrode, a top electrode TiN and a protection electrode Pt thereof are fabricated by using physical vapor deposition (PVD) method or other film formation method in IC process.

The resistive characteristic, erase characteristic and retention at high temperature of the resistive memory (W/WOx/Cu) fabricated by the embodiment are similar to that of the resistive memory fabricated by the embodiment 1, and show a good RRAM characteristic.

Although specific embodiments of the specification describe a structure, material and fabrication method of a RRAM of the present invention in which a bottom electrode is oxidized to form a resistive material layer, those skilled in the art of field will appreciate that, implementation of the present invention is not limited to the described embodiments. For example, the material of the bottom electrode may be also selected from metal material which can be formed into a corresponding metal oxide such as Al, Ti, Hf, Zr, Y. Furthermore, the top electrode may be substituted by a typical metal electrode in a RRAM fabrication process.

A resistive memory fabricated based on a bottom electrode oxidation method and a method for fabricating the same are described through the above specific embodiments. However, those skilled in the art should understand that, any change or modification may be made to the present invention without departing from the substantial scope of the present invention, and the present invention is not limited to the contents disclosed in the embodiments in this specification.

What is claimed is:

1. A method for fabricating a resistive memory, comprising:
1) fabricating a bottom electrode over a substrate;
2) partially oxidizing a metal of the bottom electrode through dry-oxygen oxidation or wet-oxygen oxidation to form a metal oxide with a thickness of 3 nm to 50 nm as a resistive material layer; and
3) fabricating a top electrode over the resistive material layer.

2. The method of claim 1, wherein, the bottom electrode and the top electrode are fabricated by using a PVD method or other film formation method in IC process.

3. The method of claim 1, wherein, the bottom electrode is W electrode, Ta electrode, Ti electrode, Al electrode, Y electrode or Hf electrode.

4. The method of claim 1, wherein, the metal of the bottom electrode has a thickness in a range of 100 nm-300 nm.

5. The method of claim 1, wherein, the top electrode is Pt electrode, TiN electrode, Cu electrode or Ag electrode.

6. The method of claim 1, wherein, a protection electrode is formed on the top electrode, and the protection electrode is made of platinum, titanium or gold.
